(19) United States
(12) Patent Application Publication
(10) Pub. No.: US 2024/0322673 A1
(43) Pub. Date: Sep. 26, 2024

(54) BASE PLATE AND SINGLE-PHASE MODULE OF AN INVERTER, INVERTER AND POWER ELECTRONICS

(71) Applicant: ZF Friedrichshafen AG, Friedrichshafen (DE)

(72) Inventors: Ake Ewald, Bayreuth (DE); Florian Ellerbeck, Willmering (DE)

(73) Assignee: ZF Friedrichshafen AG, Friedrichshafen (DE)

(21) Appl. No.: 18/606,937

(22) Filed: Mar. 15, 2024

(30) Foreign Application Priority Data
Mar. 21, 2023 (DE) 10 2023 202 462.4

(51) Int. Cl. H02M 1/32; H02M 7/00; H02M 7/5387; H05K 7/14; H05K 7/20

(52) U.S. Cl. CPC H02M 1/327; H02M 7/003; H02M 7/5387; H05K 7/14329; H05K 7/2089

(57) ABSTRACT

A base plate of a single-phase or multi-phase module of an inverter of an electric drive of an at least partially electrically driven vehicle, wherein the base plate is formed from at least two sub-assemblies, of which a first sub-assembly is formed as a base structure of lightweight construction, and a second sub-assembly is formed as at least one heat-conducting element which is integrated into the base structure and has one or more receiving regions for fastening in each case one semiconductor package on an upper side and a cooling structure on an underside opposite the upper side, wherein the cooling structure is arranged at least in the region of the receiving region(s).

### CROSS-REFERENCE TO RELATED APPLICATION

This application claims priority to German Application No. DE 10 2023 202 462.4, filed on Mar. 21, 2023, the entirety of which is hereby fully incorporated by reference herein.

### FIELD

The present disclosure relates to the field of electromobility, in particular of electronic modules for an electric drive.

### BACKGROUND

The use of electronic modules, such as power electronics modules, in motor vehicles has increased significantly in recent decades. On the one hand, this is due to the need to improve fuel economy and vehicle performance, and, on the other hand, is due to advances in semiconductor technology. The main component of such an electronic module, also known as power electronics, are an electronic control unit (ECU), which is connected to or forms part of the vehicle control unit(s) and receives control signals and/or information based on, for example, driving behavior or signals from other control units, and a DC/AC inverter, which is used to supply electrical machines such as electric motors or generators with a multi-phase alternating current (AC). This involves converting a direct current generated by a DC energy source, such as a battery or accumulator, into a multi-phase alternating current. For this purpose, the inverters comprise a large number of electronic components with which bridge circuits (such as half bridges) are realized, for example semiconductor power switches, which are also referred to as power semiconductors. In addition, a DC/DC converter may also be present in the power electronics.

### SUMMARY

Since one aim is to make electrically powered vehicles as light as possible, for example to enable the longest possible range, one aim of the present disclosure is to provide a reduction in weight in the region of the inverter and its components.

This object is achieved by the features as disclosed herein. Advantageous embodiments are also disclosed herein.

What is proposed is a base plate of a single-phase or multi-phase module of an inverter of an electric drive of an at least partially electrically driven vehicle, wherein the base plate is formed from at least two sub-assemblies, of which a first sub-assembly is formed as a base structure of lightweight construction, and a second sub-assembly is formed as at least one heat-conducting element which is integrated into the base structure and has one or more receiving regions for fastening in each case a semiconductor package on an upper side and a cooling structure on an underside, opposite the upper side, wherein the cooling structure is arranged at least in the region of the receiving region(s).

In one embodiment, the heat-conducting element(s) are formed as a continuous structure, or as a plurality of individual structures arranged next to each other.

In one embodiment, the base structure is formed from aluminum or a plastic with a predetermined specific density, and the heat-conducting element(s) are formed from copper or aluminum.

In one embodiment, the heat-conducting element(s) and the base structure are connected to each other by an integrally bonded or frictional connection and in a gas-tight manner.

In one embodiment, the heat-conducting element(s) and the base structure are interconnected by butt joints or by lap joints.

In one embodiment, the base structure has, in the region in which a heat-conducting element is provided, an undercut on at least two opposing regions as connection region, wherein the heat-conducting element has supports corresponding to the undercuts as connection region in such a way that it bears against the undercuts of the base structure after assembly from an underside of the base plate, and the supports and the undercuts are connected to each other.

In one embodiment, the base structure has, in the region in which a heat-conducting element is provided, a support on at least two opposing regions as a connection region, wherein the heat-conducting element has undercuts corresponding to the supports as a connection region in such a way that it rests on the supports of the base structure after assembly from an upper side of the base plate, and the undercuts and the supports are connected to each other.

In one embodiment, the base structure and the heat-conducting element are connected by a tongue-and-groove connection as connection regions, wherein either the base structure has a groove and the heat-conducting element has a tongue, or wherein the base structure has a tongue and the heat-conducting element has a groove.

In one embodiment, the connection regions of heat-conducting element and base structure are formed in such a way that the region of the connection regions of a heat-conducting element on the underside of the base plate extends from the cooling structure in a predetermined length in the direction of the base structure.

In one embodiment, the heat-conducting element or elements are formed in such a way that they are flush with the base structure or protrude beyond the base structure by a predetermined height.

Furthermore, a single-phase module or a multi-phase module is proposed, comprising the base plate, as well as at least one half-bridge arranged on the base plate and per phase, which half-bridge is formed from two semiconductor packages fixed on two heat-conducting elements arranged opposite each other, or which is formed as a single semiconductor package fixed on a single heat-conducting element, and DC and AC busbars arranged stacked on the half-bridge(s) and electrically contacted with the associated current terminals.

Power electronics for operating a three-phase electric motor of a vehicle are also proposed, wherein the power electronics have an inverter which is formed from a multi-phase module or, per phase, from a single-phase module, as well as at least one ECU which is connected to the electric motor for open-loop and closed-loop control thereof and to the inverter.

Furthermore, an electric drive for a vehicle is proposed, comprising a three-phase electric motor and an accumulator, as well as the power electronics connected to both.

Furthermore, a vehicle is proposed comprising the electric drive, which is formed as an electric axle drive.

Further features and advantages of the present disclosure will become apparent from the following description of exemplary embodiments of the present disclosure, with reference to the figures in the drawing, which shows details according to the present disclosure, and from the claims. The individual features can be realized individually or in any combination in a variant of the present disclosure.

Preferred embodiments of the present disclosure are explained in greater detail below with reference to the appended figures.

### BRIEF DESCRIPTION OF THE DRAWINGS

FIG. 1 shows a sectional view of a basic arrangement of semiconductor package and base plate according to the prior art.

FIG. 2 shows a plan view of a single-phase module equipped with semiconductor packages according to the prior art.

FIG. 3 shows an oblique plan view of a base plate according to an embodiment of the present disclosure.

FIG. 4 shows a sectional view of the base plate shown in FIG. 3.

FIG. 5 shows a plan view of a base plate according to a further embodiment of the present disclosure.

FIG. 6 shows a sectional view of the base plate shown in FIG. 5.

FIG. 7 shows a plan view of a base plate according to a further embodiment of the present disclosure.

FIG. 8 shows a sectional view of the base plate shown in FIG. 7.

FIGS. 9, 10, 11, and 12 show sectional views of a base plate according to further embodiments of the present disclosure.

### DETAILED DESCRIPTION

In the following figure descriptions, like elements or functions are provided with like reference signs.

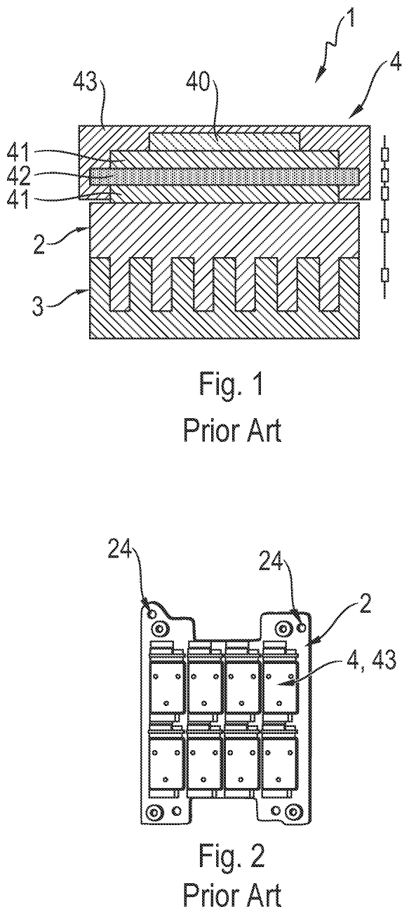

Current single-phase modules 1, as shown in FIG. 1 as a schematic structure for a part on which a semiconductor package 4 is arranged, are distinguished in that the switching semiconductors 40 must be actively cooled in order to dissipate the switching and conduction losses. To dissipate the losses, a heat conduction path is established from the semiconductor 40 into a cooling medium 3 and is distinguished in that the thermal resistance should be as low as possible. The thermal path (resistors are shown on the far right) is usually built up from the components shown in FIG. 1: copper 41, ceramic 42, copper 41, base plate 2, cooling medium 3, wherein the printed circuit board formed from the layers of copper 41, followed by ceramic 42, followed by copper 41 represent an electrically insulating layer. Such a printed circuit board can be, for example, a DBC or an AMB printed circuit board.

Currently, base plates 2, also known as cooling plates, are embodied with a large surface area, as shown in FIG. 2, so that they also have sealing and mounting elements such as screw holes 24 for fastening in the inverter housing. For optimum cooling, the base plates 2 are often made of copper, so that the regions that are not to be cooled directly are also made of copper. This leads to a relatively high weight of the component (the base plate 2), which contradicts the current desire for lightweight construction in vehicle construction and consumes costs and resources.

In order to make inverters (DC/AC inverters) in the vehicle lighter, it is proposed to change the structure of the base plate 2, as described below. The aim here is to provide the best possible cooling of the semiconductors 40 (power semiconductors) of the semiconductor packages 1 placed on the base plate 2, more precisely in the receiving regions 22 provided for this purpose (arranged in the housing 43), while still achieving a lower weight than previously possible.

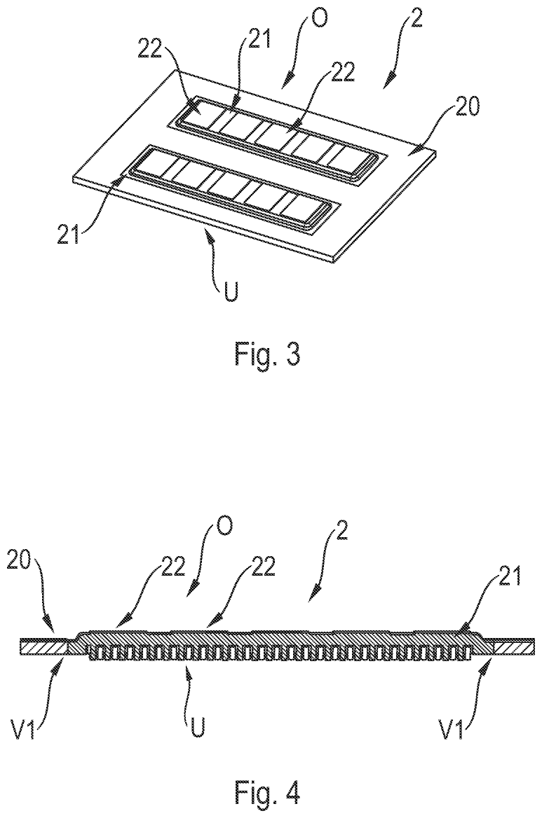

This is achieved by dividing the base plate 2 into two interconnected sub-assemblies, as shown in FIG. 3. A first sub-assembly is formed as a lightweight base structure 20, and a second sub-assembly is formed as at least one heat-conducting element 21 integrated into the base structure 20 with one or more receiving regions 22 for the semiconductor packages 4. Depending on the configuration of the semiconductor packages 4, only one heat-conducting element 21 is present or two or more heat-conducting elements 21 are present. In the event that a plurality of heat-conducting elements 21 are provided, these are located opposite each other at a distance on the same side (e.g. the upper side O) of the base structure 20. In principle, a heat-conducting element 21 is provided underneath each semiconductor package 4.

For example, half bridges are installed in an inverter, each of which half-bridges has a high-side switch and a low-side switch that are arranged on one or more corresponding heat-conducting elements 21, in particular opposite each other, as shown in FIG. 3. FIG. 2 shows individual switches (low-side or high-side) formed as semiconductor packages 4. In an embodiment not shown in the figures, however, half-bridge modules can also be provided as semiconductor packages 4, in which at least one high-side and one low-side switch are already provided in a single package, which is then referred to as semiconductor package 4. These half-bridge modules are then arranged on a single heat-conducting element 21, which represents the second sub-assembly. Substantially, the first sub-assembly, i.e., the base structure 20, is a lightweight structure made of a material with a low specific density, e.g. aluminum or a plastic. When selecting the material, care must of course be taken to ensure that the necessary stability for use in the automotive sector is present and that connection to other components of the inverter is as simple as possible. This means, for example, that screw holes 24 can also be provided.

The second sub-assembly, i.e., the heat-conducting element(s) 21, are substantially manufactured as inlets for the semiconductor packages 4 and are designed in different ways. These inlets have an optimized cooling structure 23, e.g., via pinfins, as shown in FIGS. 4, 6, 8 and 9-12. Other structures, such as meanders, bionically inspired designs etc., are also possible. The material for the cooling structure 23 is intended for maximized heat conduction and is thus preferably made of copper, alternatively of aluminum or another heat-conducting material. The material can also be coated. After assembly in the housing of the inverter, the cooling structure 23 is immersed in a cooling medium 3 for better heat dissipation, as indicated in FIG. 1.

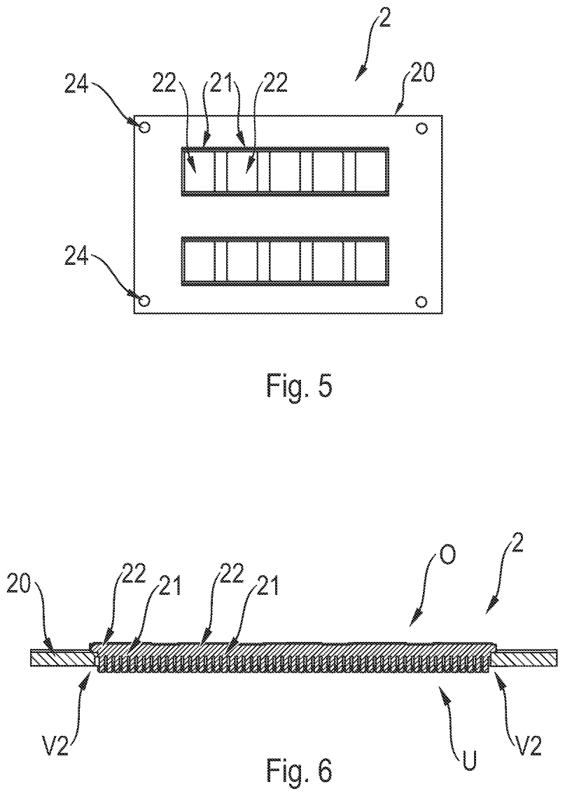

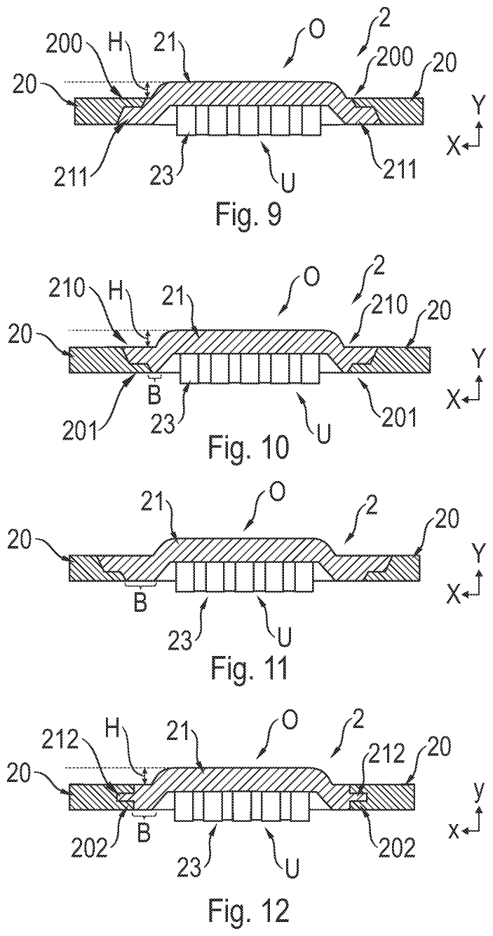

FIGS. 3-6 show two embodiments in which the semiconductor packages 4 are formed as individual switches, under each of which a heat-conducting element 21 is provided. In this embodiment, the heat-conducting element(s) 21 are each formed as a continuous structure, on which a plurality of receiving regions 22 for respective semiconductor packages 4 are provided next to each other and adjacent to each other, which receiving regions point in the direction of the upper side O of the base plate 2. The cooling structure 23 is provided on the side of the heat-conducting elements 21 pointing toward the underside U of the base plate, as can be clearly seen in the sectional view in FIGS. 4 and 6. Only the connection between the first and second sub-assemblies is made in different ways in FIGS. 3/4 and 5/6, as also described below in conjunction with FIGS. 9 to 12.

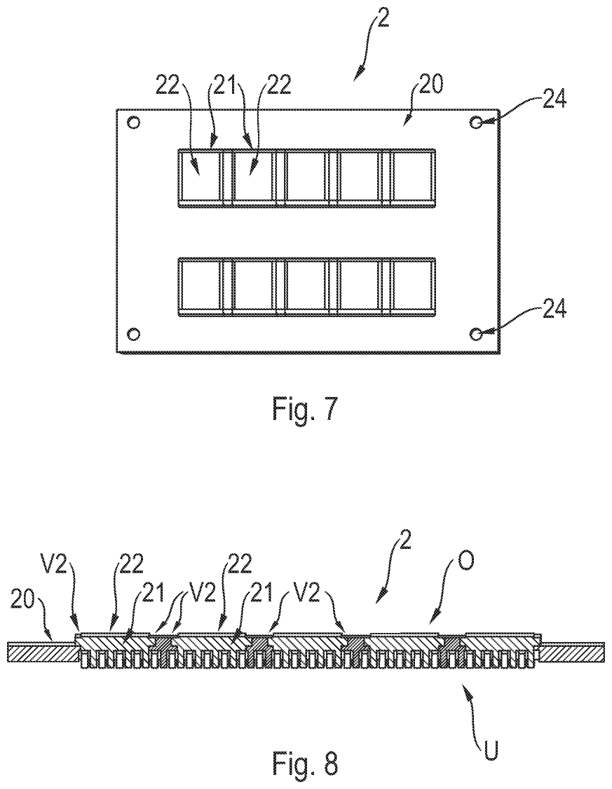

FIGS. 7 and 8 show a further alternative embodiment in which the semiconductor packages 4 are formed as individual switches, under each of which a heat-conducting element 21 is provided, wherein the heat-conducting elements 21 are also formed as individual components which are arranged adjacent to each other and at a distance from each other. The base structure 20 is provided in the region of the spacing, which saves further weight. In this embodiment, each heat-conducting element 21 has its own cooling structure 23. This design provides a production-related advantage, since the heat-conducting elements 21 can be manufactured as individual components and therefore only a single tool is required, whereas with the heat-conducting elements 21 formed as a continuous structure, a new tool must also be used if the number of receiving regions 22 is changed.

In the proposed concept, the connection of the materials of the two sub-assemblies poses a challenge. The connection between the base structure 20 and the heat-conducting element(s) 21 (only the plural is used below) must (depending on the specific application) withstand the respective temperature, pressure and tightness requirements, as well as take into account the manufacturing process and the successive steps involved. The two sub-assemblies are therefore connected by an integrally bonded, gas-tight connection, e.g. by welding, soldering, gluing, or also by a frictional connection if this can be made gas-tight.

As shown in the embodiment in FIG. 4 and denoted by reference sign V1, the sub-assemblies, i.e., the base structure 20 and the heat-conducting elements 21, can be connected to each other by butt-jointing on all side regions of the heat-conducting elements 21. Care must be taken here to ensure that a very firm connection is created that is resistant to forces acting from the underside U and the upper side O.

As shown in the embodiment in FIGS. 6 and 8 and denoted by reference sign V2, the sub-assemblies, i.e., the base structure 20 and the heat-conducting elements 21, can be connected to each other by a lap joint on all side regions of the heat-conducting elements 21. This means that, in this case, the heat-conducting elements 21 have a projection on side regions where no cooling structure is provided on the underside and with which they rest on the base structure 20. The advantage here is that the heat-conducting elements 21 thus protrude above the base structure 20 by a predetermined height H, as indicated in FIGS. 9 to 12, and any required air gaps can therefore be maintained directly. In this design, too, care must be taken to ensure that a very strong connection is created that is resistant to the forces acting from the underside U and the upper side O.

The two sub-assemblies can also be joined, for example, by inserting the heat-conducting elements 21 into a mold and then overmolding or encapsulating them with the base structure 20 if the material is an injection-moldable or castable material. This is a possible manufacturing option in the embodiment shown in FIGS. 7 and 8, for example.

As in the embodiments shown in FIGS. 9-12, the sub-assemblies, i.e., the base structure 20 and the heat-conducting elements 21, can be connected by corresponding interlocking structures.

In the embodiment shown in FIG. 9, the base structure 20 has an undercut 200 and the heat-conducting elements 21 have a support 211 as a counter-structure. In order to bring the two sub-assemblies together, i.e., to connect them to each other, the heat-conducting elements 21 are brought from the underside U of the base plate 2 through the recess provided therein until the support 211 rests against the undercut 200 and can be connected to it. The semiconductor packages 4 can then be placed on the recesses 22 and attached to them. The connection between base structure 20 and heat-conducting elements 21 is created by a temperature-resistant process, e.g., hard-soldering with high-temperature solder, in order to survive the subsequent sintering process, by which the semiconductor packages 4 are fixed to the receiving regions 22, undamaged. The advantage of this design is that it is self-locking against pressure from the underside U, which can be exerted by the cooling medium 23, for example. The length of the support 211 must be selected here at least such that the support 211 does not tear off the undercut 200 at a (maximum predetermined) pressure from the underside U. In a further embodiment, the length (in the X direction) of the support 211 is selected to be longer than the minimum required in order to provide an enlarged cooling surface. The length depends here on the additional cooling required.

In the embodiment shown in FIG. 10, the base structure 20 has a support 201 and the heat-conducting elements 21 have an undercut 210 as a counter-structure. In order to bring the two sub-assemblies together, i.e., to connect them, the heat-conducting elements 21 are brought from the upper side O of the base plate 2 through the recess provided therein until the support 201 rests against the undercut 210 and can be connected thereto. In this embodiment, the semiconductor packages 4 can be applied to the recesses 22 in advance and attached to them. This reduces the thermal requirements for the connection point, as only the operating parameters need to be withstood. The advantage of this design is that it is self-locking against pressure from the upper side O. The length of the support 201 must at least be selected such that the support 201 does not tear off the undercut 210 at a (maximum predetermined) pressure from the upper side O. In a further embodiment, the region B of the heat-conducting element 21 between the end (in the X direction) of the undercut 210 and the start of the cooling structure 23 can be extended in the direction of the base structure 20 in order to provide an enlarged cooling surface, as shown in FIG. 11. This means that the base structure 20 has a larger recess to accommodate the heat-conducting element 21. The length depends here on the additional cooling required.

In the embodiment shown in FIG. 12, base structure 20 and heat-conducting element 21 are connected by a tongue-and-groove connection as connection regions. Either, as shown in FIG. 12, the base structure 20 can have a groove 202 and the heat-conducting element 21 can have a tongue 212. Alternatively, the base structure 20 has a tongue and the heat-conducting element 21 has a groove (not shown). In this embodiment, it also makes sense for the base structure 2 to be injection-molded or cast around the heat-conducting elements 21. It can also be provided that the base structure 20 is formed in two parts and is pushed onto the heat-conducting elements 21. The advantage of this design is that it is self-locking against pressure from the underside U and also from the upper side O, as well as against shearing forces. In this design, the region B can also be extended (in the direction of the base structure 20, i.e., X-direction) in order to provide an increased cooling surface. The length depends here on the additional cooling required.

The joining processes described can be supported by coatings or surface structuring (ordered or unordered) of the joining surfaces.

As already described in conjunction with the individual figures, the size of the edge regions of the heat-conducting elements 21 can be varied depending on the stipulated requirements. By increasing the size of the support, for example, more solder can be applied to the connection. The heat transfer can be increased by making the cooling medium side (underside U) wider (extension in the X direction).

The distances, materials and shape of the heat-conducting elements 21 must be selected accordingly in order to maintain the specified clearances between the busbars (HV level), arranged above the base structure 20, and the base structure 20 (GND level). In one embodiment, the heat-conducting elements 21 are formed in such a way that they are flush with the base structure 20. In an alternative embodiment, the heat-conducting elements 21 are formed in such a way that they protrude above the base structure 20 by a predetermined height H.

Furthermore, suitable shapes may be arranged on or formed in the base structure 20 to stiffen the base structure 20, such as a ribbed structure.

The proposed base plate 2 is preferably used in single-phase modules 1, which are used in an inverter, as a carrier and cooling plate in order to be connected to a housing of the inverter on its underside U, which is provided with the cooling structure 23, and in order to carry further components of the inverter, such as AC and DC busbars, as well as printed circuit boards and other components, on its upper side O (more precisely the semiconductor packages 4 arranged thereon). Single-phase modules 1 are modules that each represent one phase of an inverter and can be connected together to form a multi-phase module. The base plate 2 can, of course, also be used for multi-phase modules in which several phases of the inverter are realized on a base plate 2.

As already described, the base plate 2 serves as a carrier plate. Here, regions on which no semiconductor packages 4 to be cooled are arranged are formed in lightweight construction from a material that is sufficiently stable for the respective application, such as aluminum or plastic. Furthermore, it must have good thermal conductivity in the regions where the semiconductor packages 4 are arranged in order to be able to cool the semiconductors 40 provided therein. For this purpose, this part of the base plate 2 is formed as a heat-conducting element 21 and is made of a material such as copper. This provides sufficient heat dissipation of the semiconductor packages 4. The base plate 2 advantageously provides ground potential GND.

The semiconductor packages 4 are generally arranged opposite each other so that two of them form a half-bridge, wherein one semiconductor package 4 serves as a high-side switch and the other as a low-side switch, each of which can have power semiconductors, e.g., MOSFETs, IGBTs, etc., connected in parallel with each other. One or more half-bridges can be provided per phase. DC and AC busbars are arranged above the half-bridges and electrically contacted with the associated current terminals of the half bridges. Semiconductor package 4 refers to one or more encapsulated (located in a housing) power semiconductors (chips) that serve as high-side or low-side switches, including (non-encapsulated) connection legs for electrical or signal contacting. The term semiconductor package 4 also refers to a half-bridge module in which the high-side and low-side switches are already installed together in a housing.

Furthermore, a single-phase module 1 with a base plate 2 and at least two opposing semiconductor packages 4, which form a half-bridge, is proposed. In each case, one of the semiconductor packages 4 is formed as a high-side switch and the other as a low-side switch. Furthermore, a multi-phase module is proposed which differs from the single-phase module 1 only in that the base plate 2 is not used for only one phase of the inverter, but several, in particular three, phases are provided on a single base plate 2. Thus, for example, a three-phase module can be produced with only one base plate 2 instead of arranging three single-phase modules 1 together (next to each other).

The number of half bridges depends here on the required power of the inverter and the semiconductor packages 4 used.

The base plate is advantageously used in power electronics, preferably used in an electric drive of a vehicle comprising a three-phase electric motor and an accumulator. The power electronics have an inverter with several phases and are connected to the electric motor and accumulator in order to generate direct current from the accumulator into alternating current that can be used for the electric motor by the inverter in order to drive the electric motor. An ECU, i.e., an electronic control unit, is provided to control the inverter. The ECU is connected to the electric motor for its open-loop and closed-loop control and to the inverter. In particular, the electric motor is an electric axle drive in this case.

Advantageously, a vehicle, e.g., a passenger car or a commercial vehicle, has at least one such drive. The vehicle is in particular a commercial vehicle such as a truck or a bus, or a passenger car. The power electronics module (i.e., the power electronics) comprises a DC/AC inverter with the structure described. It may also comprise an AC/DC rectifier, a DC/DC converter, a transformer and/or another electrical converter or a part of such a converter, or may be a part thereof. In particular, the power electronics module is used to power an electric machine, for example an electric motor and/or a generator. A DC/AC inverter is preferably used to generate a multi-phase alternating current from a direct current generated by a DC voltage from an energy source, such as a battery.

### LIST OF REFERENCE SIGNS

1 single-phase module
2 base plate
20 base structure
   200 undercut
   201 support
   202 groove
21 heat-conducting element
   210 undercut of 21
   211 support of 21
   212 tongue
22 receiving region for 4
23 cooling structure (pinfins, etc.)
24 screw holes
3 cooling medium
4 semiconductor package
40 semiconductors
41 copper
42 ceramics
43 housing
U underside of base plate
O upper side of base plate
B region between end 201 and start 23
H height
1 butt joint of 20 and 21
V2 lap joint between 20 and 21

1. A base plate of a single-phase or multi-phase module of an inverter of an electric drive of an at least partially electrically driven vehicle, the base plate comprising:
at least two sub-assemblies, comprising:
a first sub-assembly formed as a base structure of lightweight construction; and
a second sub-assembly formed as at least one heat-conducting element which is integrated into the base structure and has one or more receiving regions for fastening in each case one semiconductor package on an upper side and a cooling structure on an underside opposite the upper side, wherein the cooling structure is arranged at least in a region of the receiving region.

2. The base plate as claimed in claim 1, wherein the at least one heat-conducting element is formed as a continuous structure, or is formed as a plurality of individual structures arranged next to each other.

3. The base plate as claimed in claim 1, wherein the base structure is formed from aluminum or a plastic with a predetermined specific density, and wherein the at least one heat-conducting element is formed from copper or aluminum.

4. The base plate as claimed in claim 1, wherein the at least one heat-conducting element and the base structure are connected to each other by an integrally bonded or frictional connection and in a gas-tight manner.

5. The base plate as claimed in claim 1, wherein the at least one heat-conducting element and the base structure are connected to each other by butt-jointing, or are connected to each other by a lap joint.

6. The base plate as claimed in claim 1,
wherein the base structure comprises:
in a region in which a heat-conducting element is provided, an undercut on at least two opposing regions as a connection region, wherein the at least one heat-conducting element has supports corresponding to the undercuts as a connection region in such a way that it bears against the undercuts of the base structure after assembly from an underside of the base plate, and the supports and the undercuts are connected to each other.

7. The base plate as claimed in claim 6, wherein the connection regions of the at least one heat-conducting element and base structure are formed in such a way that a region of the connection regions of a heat-conducting element on the underside of the base plate extends from the cooling structure in a predetermined length in a direction of the base structure.

8. The base plate as claimed in claim 1,
wherein the base structure comprises:
in a region in which a heat-conducting element is provided, a support on at least two opposing regions as a connection region, wherein the at least one heat-conducting element has undercuts corresponding to the supports as a connection region in such a way that it rests on the supports of the base structure after assembly from an upper side of the base plate, and the undercuts and the supports are connected to each other.

9. The base plate as claimed in claim 8, wherein the connection regions of the at least one heat-conducting element and base structure are formed in such a way that a region of the connection regions of a heat-conducting element on the underside of the base plate extends from the cooling structure in a predetermined length in a direction of the base structure.

10. The base plate as claimed in claim 1, wherein the base structure and the at least one heat-conducting element are connected by a tongue-and-groove joint as connection regions, wherein either the base structure has a groove and the heat-conducting element has a tongue, or wherein the base structure has a tongue and the heat-conducting element has a groove.

11. The base plate as claimed in claim 1, wherein the at least one heat-conducting element is formed in such a way that it is flush with the base structure or projects beyond the base structure by a predetermined height.

12. A single-phase module or multi-phase module, comprising:
the base plate as claimed in claim 1;
at least one half-bridge arranged on the base plate per phase, which half-bridge is formed from at least two semiconductor packages fixed on two heat-conducting elements arranged opposite each other, or which half-bridge is formed as a single semiconductor package fixed on a single heat-conducting element; and
DC and AC busbars arranged stacked on the at least one half bridge and electrically contacted with associated power connections.

13. Power electronics for operating a three-phase electric motor of a vehicle, the power electronics comprising:
an inverter comprising the single phase module or multi-phase module as claimed in claim 12; and
at least one ECU, which is connected to the electric motor for open-loop and closed-loop control thereof and to the inverter.

14. An electric drive of a vehicle, comprising:
a three-phase electric motor;
an accumulator; and
the power electronics as claimed in claim 13 connected to the three-phase electric motor and the accumulator.

15. A vehicle, comprising:
the electric drive as claimed in claim 14, which is formed as an electric axle drive.
